(19) United States
(12) Patent Application Publication
(10) Pub. No.: US 2025/0159880 A1
(43) Pub. Date: May 15, 2025

(54) ERASABLE PROGRAMMABLE SINGLE-PLOY NON-VOLATILE MEMORY CELL

(71) Applicant: eMemory Technology Inc., Hsin-chu (TW)

(72) Inventor: Hsueh-Wei CHEN, Hsinchu County (TW)

(21) Appl. No.: 18/940,879

(22) Filed: Nov. 8, 2024

Related U.S. Application Data
(60) Provisional application No. 63/598,558, filed on Nov. 14, 2023.

(51) Int. Cl. H10B 41/60; H10B 41/35

(52) U.S. Cl. CPC H10B 41/60; H10B 41/35

(57) ABSTRACT

An erasable programmable single-poly non-volatile memory cell is provided. In the memory cell, plural doped regions are formed through different fabricating procedures. The memory cell includes a select transistor and a floating gate transistor. The channel length of the floating gate transistor is smaller than the channel length of the select transistor. The doping step in the manufacturing method is modified. Consequently, plural doped regions have different parameters and characteristics, and the channel resistance value of the floating gate transistor will be greater than that of the select transistor.

This application claims the benefit of U.S. provisional application Ser. No. 63/598,558, filed Nov. 14, 2023, the subject matters of which is incorporated herein by reference.

### FIELD OF THE INVENTION

The present invention relates to a non-volatile memory, and more particularly to an erasable programmable single-poly non-volatile memory cell.

### BACKGROUND OF THE INVENTION

As is well known, a memory cell of a non-volatile memory comprises a storage unit. For example, the storage unit is a floating gate transistor. The storage state of the memory cell is determined according to the number of charges stored in the floating gate of the floating gate transistor.

In order to be compatible with the standard CMOS manufacturing process, the memory cell of the conventional non-volatile memory is equipped with a single-poly floating gate transistor. The floating gate transistor and associated electronic devices are collaboratively formed as a single-poly non-volatile memory cell.

For example, an erasable programmable single-poly non-volatile memory is disclosed in U.S. Pat. No. 8,941,167. FIG. 1A is a schematic top view illustrating a conventional single-poly non-volatile memory cell. FIG. 1B is a schematic cross-sectional view illustrating the conventional single-poly non-volatile memory cell and taken along the line a1-a1. FIG. 1C is a schematic cross-sectional view illustrating the conventional single-poly non-volatile memory cell and taken along the line b1-b1. FIG. 1D is a schematic equivalent circuit diagram of the conventional single-poly non-volatile memory cell.

As shown in FIGS. 1A to 1D, three p-type doped regions 131, 132 and 133 are formed in an N-well region NW. In addition, a select gate 134 and a floating gate 136 formed of a polysilicon layer are located over the areas between the p-type doped regions 131, 132 and 133. An n-type doped region 138 is formed in a P-well region PW. The floating gate 136 is externally extended from an isolation structure 139 and located beside the n-type doped region 138. For example, the isolation structure 139 is a shallow trench isolation (STI) structure.

The conventional single-poly non-volatile memory cell comprises a select transistor M_{S}, a floating gate transistor M_{F} and an n-type transistor Mₙ. The select transistor M_{S} and the floating gate transistor M_{F} are p-type transistors and constructed in the N-well region NW. The n-type transistor Mₙ is constructed in the P-well region PW.

The p-type doped region 131, the p-type doped region 132, the select gate 134 and the N-well region NW are collaboratively formed as the select transistor M_{S}. The p-type doped region 132, the p-type doped region 133, the floating gate 136 and the N-well region NW are collaboratively formed as the floating gate transistor M_{F}. The floating gate 136 and an assist gate region 135 are collaboratively formed as the n-type transistor Mₙ. In addition, the erase gate region 135 comprises the P-well region PW and the n-type doped region 138.

Please refer to FIG. 1D. The select gate 134 of the select transistor M_{S} receives a select gate voltage V_{SG}. The first drain/source terminal of the select transistor M_{S} receives a source line voltage V_{SL}. The body terminal of the select transistor M_{S} receives an N-well voltage V_{NW}. The first drain/source terminal of the floating gate transistor M_{F} is connected with the second drain/source terminal of the select transistor M_{S}. The second drain/source terminal of the floating gate transistor M_{F} receives a bit line voltage V_{BL}. The body terminal of the floating gate transistor M_{F} receives the N-well voltage V_{NW}.

Moreover, it may be regarded that the two drain/source terminals of the n-type transistor Mₙ are connected with the n-type doped region 138. The body terminal of the n-type transistor Mₙ receives a P-well voltage V_{PW}. The gate terminal of the n-type transistor Mₙ is connected with the floating gate 136. The two drain/source terminals of the n-type transistor Mₙ receives an erase line voltage V_{EL}. In other words, the n-type transistor Mₙ is equivalent to a metal-oxide-semiconductor capacitor, which is also referred hereinafter as a MOS capacitor.

Since the conventional memory cell comprises two transistors M_{S} and M_{F} and one capacitor, this memory cell may be referred to as a 2T1C cell.

By providing proper bias voltages as the select gate voltage V_{SG}, the source line voltage V_{SL}, the bit line voltage V_{BL}, the erase line voltage V_{EL}, the N-well voltage V_{NW} and the P-well voltage V_{PW}, a program action, an erase action or a read action can be selectively performed on the memory cell.

Generally, in the doping step of the manufacturing process of the above memory cell, all p-type doped regions 131, 132, and 133 are formed through the same fabricating procedure. Consequently, the p-type doped regions 131, 132, and 133 have the same parameters and characteristics.

Similarly, all p-type doped regions of the other memory cells disclosed in U.S. Pat. No. 8,941,167 are formed through the same fabricating procedure.

### SUMMARY OF THE INVENTION

An embodiment of the present invention provides an erasable programmable single-poly non-volatile memory cell. The erasable programmable single-poly non-volatile memory cell includes an isolation structure, a first well region, a second well region, a first gate structure and a second gate structure. The isolation structure is formed on the semiconductor substrate. A surface of the semiconductor substrate is divided into a first region and a second region by the isolation structure. The first well region is formed in the surface of the semiconductor substrate corresponding to the first region. The second well region is formed in the surface of the semiconductor substrate corresponding to the second region. The first gate structure and the second gate structure are formed on the surface of the semiconductor substrate corresponding to the first region. An area in the surface of the semiconductor substrate corresponding to the first region are divided into a first merged doped region, a second merged doped region and a third merged doped region by the first gate structure and a second gate structure. The memory cell further comprises a fourth merged doped region. The fourth merged doped region is formed in the surface of the semiconductor substrate corresponding to the second region and located beside a side of the second gate structure. The first merged doped region is located beside a first side of the first gate structure. The second merged doped region is arranged between a second side of the first gate structure and a first side of the second gate structure. The third merged doped region is located beside a second side of the second gate structure. The second gate structure is externally extended to the second region through a surface of the isolation structure. A portion of the second region is covered by the second gate structure. The first merged doped region, the first gate structure and the second merged doped region are collaboratively formed as a select transistor. The second merged doped region, the second gate structure and the third merged doped region are collaboratively formed as a floating gate transistor. The second gate structure and the fourth merged doped region are collaboratively formed as a first MOS capacitor. A channel resistance value of the floating gate transistor is greater than a channel resistance value of the select transistor.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A (prior art) is a schematic top view illustrating a conventional single-poly non-volatile memory cell;

FIG. 1B (prior art) is a schematic cross-sectional view illustrating the conventional single-poly non-volatile memory cell and taken along the line a1-a1;

FIG. 1C (prior art) is a schematic cross-sectional view illustrating the conventional single-poly non-volatile memory cell and taken along the line b1-b1;

FIG. 1D (prior art) is a schematic equivalent circuit diagram of the conventional single-poly non-volatile memory cell;

FIGS. 2A to 2H schematically illustrate the steps of a method of manufacturing a single-poly non-volatile memory cell according to a first embodiment of the present invention;

FIG. 2I is a schematic equivalent circuit diagram of the single-poly non-volatile memory cell according to the first embodiment of the present invention;

FIG. 2J is a bias voltage table illustrating the bias voltages for performing a program action, an erase action and a read action on the memory cell according to the first embodiment of the present invention;

FIG. 2K is the operations of performing the program action on the memory cell according to the first embodiment of the present invention;

FIG. 2L is the operations of performing the erase action on the memory cell according to the first embodiment of the present invention;

FIG. 2M is the operations of performing the read action on the memory cell according to the first embodiment of the present invention;

FIGS. 3A, 3B and 3C schematically illustrate a first variant example of the doping step in the manufacturing method of the first embodiment;

FIGS. 4A, 4B and 4C schematically illustrate a second variant example of the doping step in the manufacturing method of the first embodiment;

FIGS. 5A, 5B and 5C schematically illustrate a third variant example of the doping step in the manufacturing method of the first embodiment;

FIG. 6 schematically illustrates a fourth variant example of the doping step in the manufacturing method of the first embodiment;

FIGS. 7A to 7G schematically illustrate the steps of a method of manufacturing a single-poly non-volatile memory cell according to a second embodiment of the present invention; and

FIG. 7H is a schematic equivalent circuit diagram of the single-poly non-volatile memory cell according to the second embodiment of the present invention.

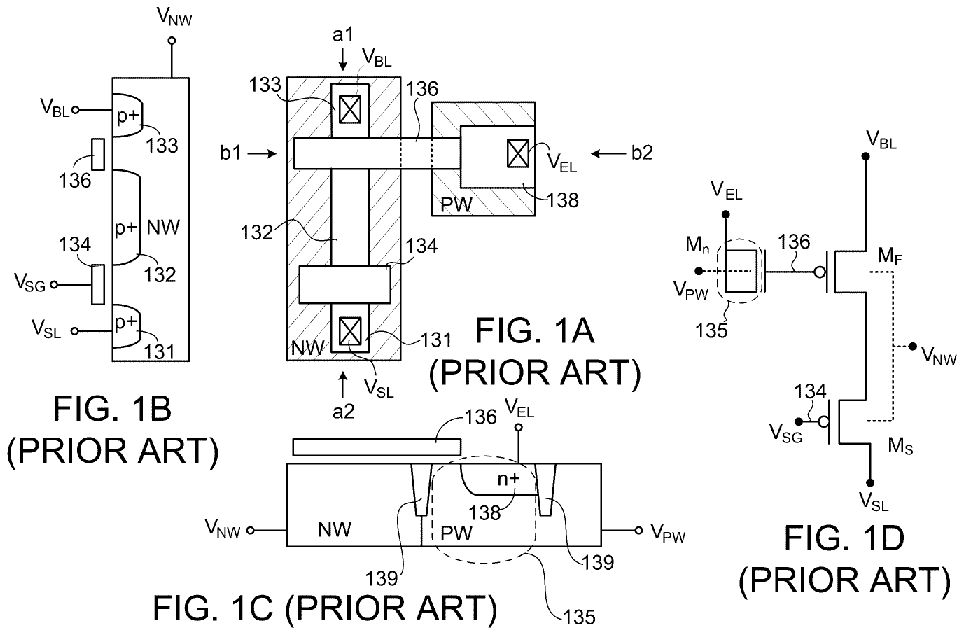

### DETAILED DESCRIPTION OF PREFERRED EMBODIMENTS

The present invention provides a single-poly non-volatile memory cell. In the memory cell, plural doped regions are formed through different fabricating procedures. That is, the doping step in the manufacturing method of the memory cell is modified. Consequently, plural doped regions have different parameters and characteristics, and the channel resistance value of the floating gate transistor will be greater than that of the select transistor. The concepts of the present invention will be described in more details as follows.

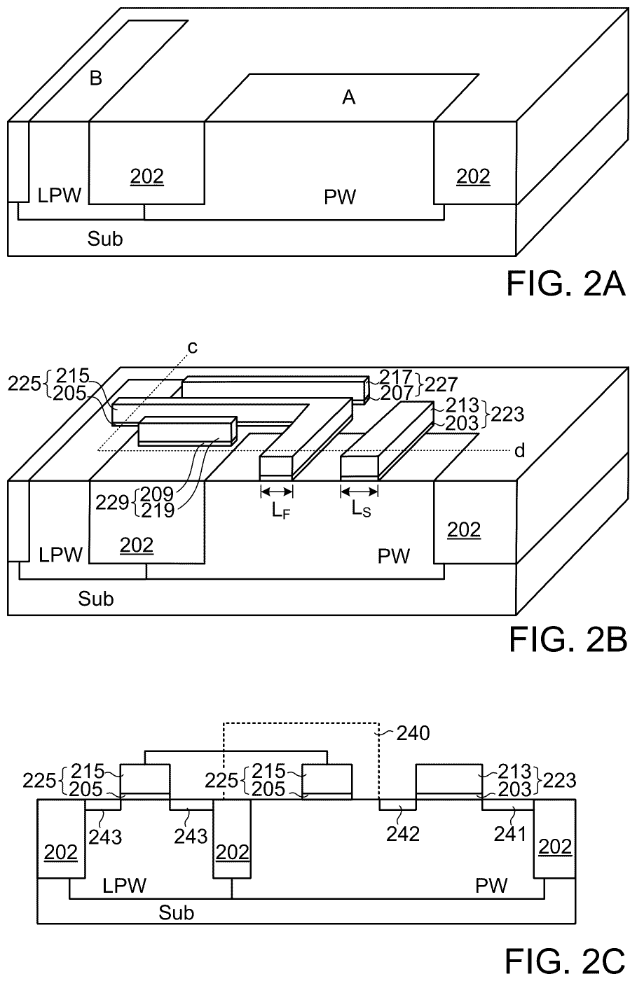

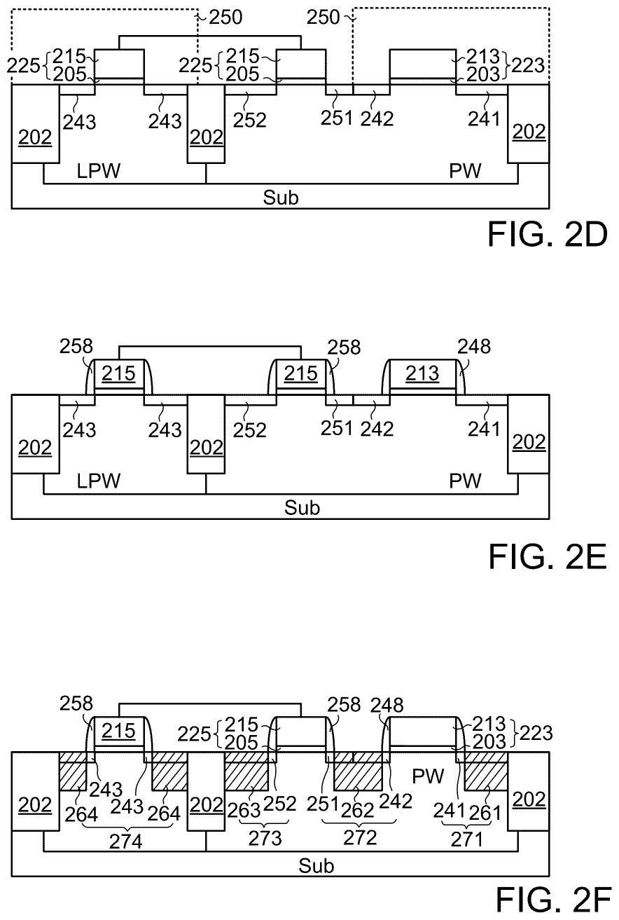

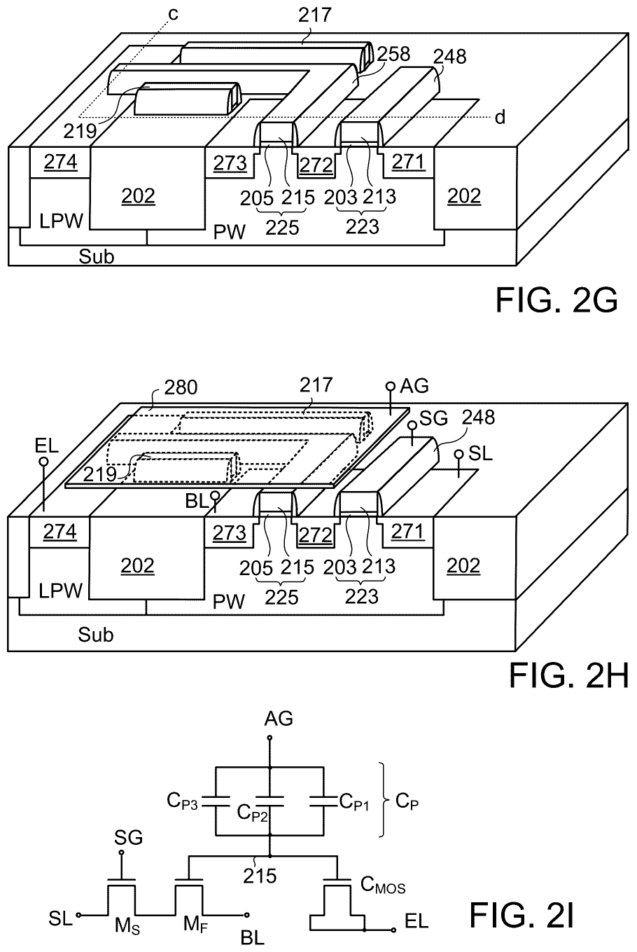

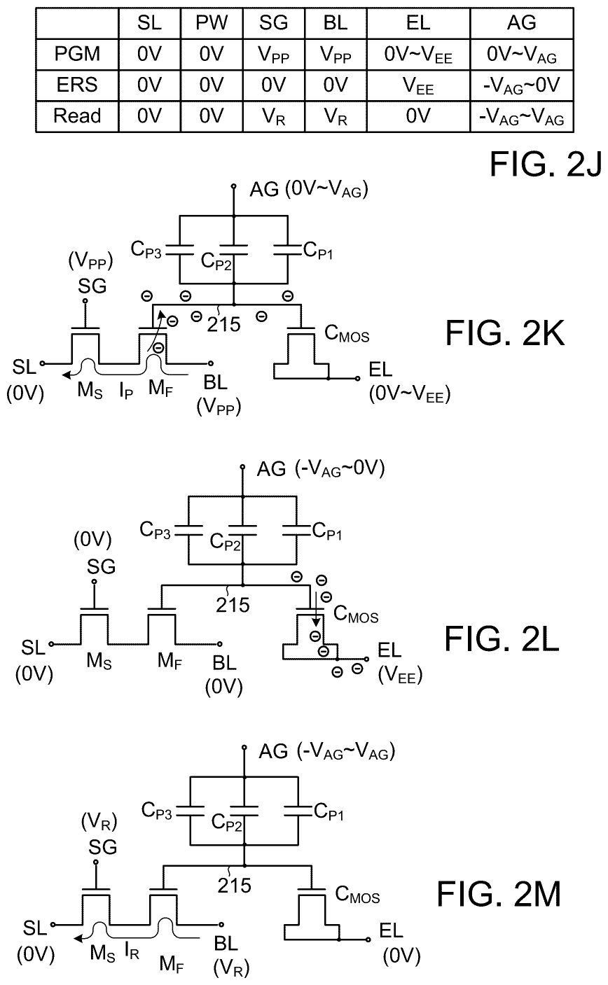

FIGS. 2A to 2H schematically illustrate the steps of a method of manufacturing a single-poly non-volatile memory cell according to a first embodiment of the present invention. FIG. 2I is a schematic equivalent circuit diagram of the single-poly non-volatile memory cell according to the first embodiment of the present invention. Hereinafter, the single-poly non-volatile memory cell is referred as a memory cell.

As shown in FIG. 2A, an isolation structure forming step is performed. An isolation structure 202 is formed on a semiconductor substrate sub. Due to the isolation structure 202, a region A and a region B are defined. The semiconductor substrate Sub is covered by the isolation structure 202. The surface of the semiconductor substrate Sub corresponding to the region A and the region B is exposed. Then, a well region forming step is performed. A first well region (e.g., a P-well region) is formed in the surface of the semiconductor substrate Sub corresponding to the region A. In addition, a second well region is formed in the surface of the semiconductor substrate Sub corresponding to the region B. For example, the second well region is a lightly doped P-well region LPW, a P-well region PW or an N-well region NW.

The, a gate structure forming step is performed. As shown in FIG. 2B, four gate oxide layers 223, 225, 227 and 229 are formed on the surface of the semiconductor substrate sub. The gate structure 223 comprises a gate dielectric layer 203 and a polysilicon gate layer 213. The gate structure 225 comprises a gate dielectric layer 205 and a polysilicon gate layer 215. The gate structure 227 comprises a gate dielectric layer 207 and a polysilicon gate layer 217. The gate structure 229 comprises a gate dielectric layer 209 and a polysilicon gate layer 219. The gate dielectric layer 203 is arranged between the polysilicon gate layer 213 and the semiconductor substrate sub. The gate dielectric layer 205 is arranged between the polysilicon gate layer 215 and the semiconductor substrate sub. The gate dielectric layer 207 is arranged between the polysilicon gate layer 217 and the semiconductor substrate sub. The gate dielectric layer 209 is arranged between the polysilicon gate layer 219 and the semiconductor substrate sub.

The two gate structures 223 and 225 are formed on the surface of the region A. In addition, the region A is divided into three sub-regions by the two gate structures 223 and 225. The gate structure 225 is L-shaped. An extension part of the gate structure 225 is externally extended to the region over the surface of the region B through the surface of the isolation structure 202. The two gate structures 227 and 229 cover the isolation structure 202 only. In addition, the two gate structures 227 and 229 are respectively located beside two opposite lateral sides of the gate structure 225. The polysilicon gate layer 215 of the gate structure 225 is served as a floating gate of a floating gate transistor. The polysilicon gate layer 213 of the gate structure 223 is served as a select gate of a select transistor. In an embodiment, the channel length L_{F} of the floating gate transistor is smaller than the channel length L_{S} of the select transistor, i.e., L_{F}<L_{S}.

As is well known, the channel resistance value of a transistor is related to the channel length and the channel width of the transistor. As the channel width is wider, the channel resistance value is smaller. As the channel width is narrower, the channel resistance value is larger. As the channel length is shorter, the channel resistance value is smaller. As the channel length is longer, the channel resistance value is larger. That is, if the n-doped regions in the structure of FIG. 2B are formed by the same fabricating process, the channel resistance value of the floating gate transistor will be smaller than the channel resistance value of the selection transistor.

In an embodiment, the doping step for doping the n-type doped regions is specially designed to change the concentration distribution of the n-type doped regions. Especially, the channel resistance value of the floating gate transistor is changed, and thus the channel resistance value of the floating gate transistor is greater than the channel resistance value of the select transistor. Hereinafter, the doping step will be described in more details with reference to the cross-sectional view of the structure shown in FIG. 2B and taken along the line c-d.

Please refer to FIG. 2C. Firstly, the gate structure 225 and its two side areas in the region A are covered with a mask 240 shown in dotted lines. The gate structure 223 and its two side areas are exposed. In addition, the region B is exposed. That is, only a part of the surface between the gate structure 223 and the gate structure 225 is covered by the mask 240, and the other part of the surface between the gate structure 223 and the gate structure 225 is not covered by the mask 240. Then, a first lightly doped drain process (LDD process) is performed. Consequently, n-type lightly doped drain regions (n-LDD regions) 241, 242 and 243 are formed in the surface of the semiconductor substrate Sub uncovered by the mask 240. The n-LDD regions 241 and 242 are formed under the surface of the region A and respectively located beside the two sides of the gate structure 223. The n-LDD region 243 is formed under the surface of the region B and located beside the gate structure 225.

Please refer to FIG. 2D. After the mask 240 is removed, the gate structure 223 (and its side areas) in the region A and the region B are covered with a mask 250 shown in dotted lines. In other words, the region previously covered by mask 240 is exposed. Then, a second LDD process is performed. Consequently, n-type lightly doped drain regions (n-LDD regions) 251 and 252 are formed in the surface of the semiconductor substrate Sub uncovered by the mask 250. The n-LDD regions 251 and 252 are formed under the surface of the region A and respectively located beside the two sides of the gate structure 225.

For example, the masks 240 and 250 are photoresists. In an embodiment, the dopant concentration of the n-LDD regions 251 and 252 is smaller than the dopant concentration of the n-LDD regions 241, 242 and 243.

Please refer to FIG. 2E. After the mask 250 is removed, a spacer 248 is formed on the sidewall of the gate structure 223, and a spacer 258 is formed on the sidewall of the gate structure 225. In addition, spacers (not shown) are formed on the sidewalls of the gate structures 227 and 229.

Please refer to FIG. 2F. Then, an n-type ion implantation process is performed on the surface of the semiconductor substrate Sub by using the two gate structures 223 and 225 and the two spacers 248 and 258 as masks. Consequently, three n-type ion implantation regions 261, 262 and 263 shown in oblique lines are formed on three sub-regions of the region A uncovered by the two gate structures 223 and 225 and the two spacers 248 and 258, and an n-type ion implantation region 264 shown in oblique lines is formed on the region B uncovered by the gate structure 225 and the spacer 258. Especially, the n-type ion implantation regions 261, 262, 263, and 264 have the highest doping concentration, and their dopant concentration is greater than the dopant concentration of the n-LDD regions 241, 242, 243, and 251.

Please refer to FIG. 2F. Then, the n-LDD region 241 and the n-type ion implantation regions 261 are collaboratively formed as a merged n-doped region 271. The merged n-doped region 271 is formed in the surface of the semiconductor substrate Sub and located beside a first side of the gate structure 223. The n-LDD region 242, the n-LDD region 251 and the n-type ion implantation regions 262 are collaboratively formed as a merged n-doped region 272. The merged n-doped region 272 is formed in the surface of the semiconductor substrate Sub and arranged between the second side of the gate structure 223 and the first side of the gate structure 225. The n-LDD region 252 and the n-type ion implantation regions 263 are collaboratively formed as a merged n-doped region 273. The merged n-doped region 273 is formed in the surface of the semiconductor substrate Sub and located beside the second side of the gate structure 225. The n-LDD region 243 and the n-type ion implantation regions 264 are collaboratively formed as a merged n-doped region 274. The merged n-doped region 274 is formed in the surface of the semiconductor substrate Sub and located beside the extension part of the gate structure 225. The perspective view of the structure of FIG. 2F is shown in FIG. 2G.

In the region A, the gate structure 223 and the merged n-doped regions 271 and 272 on its two sides are collaboratively formed as a select transistor. In addition, the gate structure 225 and the two merged n-doped regions 272 and 273 on its two sides are collaboratively formed as a floating gate transistor. In this embodiment, the floating gate transistor and the select transistor are n-type transistors and constructed in the P-well region PW. That is, the body terminal of the floating gate transistor and the body terminal of the select transistor are connected with the P-well region PW.

In the region B, the n-type doped region 274 is an erase gate region. The gate structure 225 is externally extended and located beside the erase gate region. Consequently, the erase gate region and the gate structure 225 are collaboratively formed as an n-type transistor. In addition, the n-type transistor is connected as a MOS capacitor.

Please refer to FIG. 2H. Then, a metal layer 280 is formed over the polysilicon gate layer 215. The metal layer 280 is electrically connected with the two polysilicon gate layers 217 and 219. After a step of forming metal conductor lines is completed, the memory cell of the first embodiment is fabricated. That is, the n-type doped region 271 is connected with a source line SL, the n-type doped region 273 is connected with a bit line BL, the n-type doped region 274 is connected with an erase line EL, the polysilicon gate layer 213 is connected with a select gate line SG, and the metal layer 280 is connected with an assist gate line AG.

In the memory cell of this embodiment, the gate structures 227 and 229 are disposed on the surface of the isolation structure 202. In addition, the metal layer 280 is located over the polysilicon gate structure 225. Consequently, the polysilicon gate layer 215 and the polysilicon gate layer 217 are collaboratively formed as a first poly/poly plate capacitor, and the polysilicon gate layer 215 and the polysilicon gate layer 219 are collaboratively formed as a second poly/poly plate capacitor. In addition, the polysilicon gate layer 215 and the metal layer 280 are collaboratively formed as a metal/poly plate capacitor.

As shown in FIG. 2I, the memory cell of the first embodiment comprises a select transistor M_{S}, a floating gate transistor M_{F}, a MOS capacitor C_{MOS}, a first poly/poly plate capacitor C_{P1}, a metal/poly plate capacitor C_{P2} and a second poly/poly plate capacitor C_{P3}. The first poly/poly plate capacitor C_{P1}, the metal/poly plate capacitor C_{P2} and the second poly/poly plate capacitor C_{P3} are connected with each other in parallel. The three capacitors C_{P1}, C_{P2} and C_{P3} in parallel connection can be equivalent to a plate capacitor C_{P}. It is noted that capacitor C_{P} of the memory cell is not restricted to three parallel-connected capacitors C_{P1}, C_{P2} and C_{P3}. For example, at least one capacitor is feasible.

The gate terminal of the select transistor M_{S} is connected with the select gate line SG. The first drain/source terminal of the select transistor M_{S} is connected with the source line SL. The first drain/source terminal of the floating gate transistor M_{F} is connected with the second drain/source terminal of the select transistor M_{S}. The second drain/source terminal of the floating gate transistor M_{F} is connected with the bit line BL.

The first terminal of the MOS capacitor C_{MOS} is connected with the floating gate 215. The second terminal of the MOS capacitor C_{MOS} is connected with the erase line EL. The first terminal of the first poly/poly plate capacitor C_{P1} is connected with the floating gate 215. The second terminal of the first poly/poly plate capacitor C_{P1} is connected with the assist gate line AG. The first terminal of the metal/poly plate capacitor C_{P2} is connected with the floating gate 215. The second terminal of the metal/poly plate capacitor C_{P2} is connected with the assist gate line AG. The first terminal of the second poly/poly plate capacitor C_{P3} is connected with the floating gate 215. The second terminal of the second poly/poly plate capacitor C_{P3} is connected with the assist gate line AG. That is, the first terminal of the plate capacitor C_{P} is connected with the floating gate 215, and the second terminal of the plate capacitor C_{P} is connected with the assist gate line AG.

Since the memory cell of the first embodiment comprises two transistors M_{S} and M_{F} and two capacitors C_{P} and C_{MOS}, this memory cell may be referred to as a 2T2C cell.

FIG. 2J is a bias voltage table illustrating the bias voltages for performing a program action, an erase action and a read action on the memory cell according to the first embodiment of the present invention. FIG. 2K is the operations of performing the program action on the memory cell according to the first embodiment of the present invention. FIG. 2L is the operations of performing the erase action on the memory cell according to the first embodiment of the present invention. FIG. 2M is the operations of performing the read action on the memory cell according to the first embodiment of the present invention.

When the program action (PGM), the erase action (ERS) and the read action (Read) are performed, the P-well region PW and the source line SL receives a ground voltage (0V). Moreover, the assist gate line voltage V_{AG} is higher than the erase voltage V_{EE}, the erase voltage V_{EE} is higher than the program voltage V_{PP}, the program voltage V_{PP} is higher than the read voltage V_{R}, and the read voltage V_{R} is higher than the ground voltage (0V). For example, the assist gate line voltage V_{AG} is 15V, the erase voltage V_{EE} is 12V, the program voltage V_{PP} is 9V, and the read voltage V_{R} is 5V.

Please refer to FIG. 2K. When the program action is performed, the bit line BL receives the program voltage V_{PP}, the select gate line SG receives the program voltage V_{PP}, the erase line EL receives a voltage between the ground voltage (0V) and the erase voltage V_{EE}, and the assist gate line AG receives a voltage between the ground voltage (0V) and the assist gate line voltage V_{AG}.

While the program action is performed, the select transistor M_{S} is turned on, and a program current I_{P} is generated between the bit line BL and the source line SL. When the hot carriers (e.g., electrons) of the program current I_{P} flow through a channel region corresponding to the floating gate 215, a channel hot electron (CHE) effect is generated. Due to the CHE effect, electrons are injected into the floating gate 215.

As mentioned above, the channel resistance value of the floating gate transistor M_{F} is greater than the channel resistance value of the select transistor M_{S}. After the program voltage V_{PP} is provided to the bit line BL, the voltage across the first drain/source terminal and the second drain/source terminal of the floating gate transistor M_{F} is greater than the voltage across the first drain/source terminal and the second drain/source terminal of the select transistor M_{S}. Consequently, when the program action is performed, electrons are injected into the floating gate 215 more efficiently.

Please refer to FIG. 2L. When the erase action (ERS) is performed, the bit line BL receives the ground voltage (0V), the source line SL receives the ground voltage (0V), the select gate line SG receives the ground voltage (0V), the erase line EL receives the erase voltage V_{EE}, and the assist gate line AG receives a voltage between the negative value of the assist gate line voltage −V_{AG} and the ground voltage (0V).

When the erase action is performed, the select transistor M_{S} is turned off. Under this circumstance, a Fowler-Nordheim Tunneling (FN) effect is generated between the two terminals of the MOS transistor C_{MOS}. Consequently, electrons are ejected from the floating gate 215 to the erase line EL. The voltage received by the assist gate line AG is helpful to increase the speed of ejecting the electrons from the floating gate 215. Consequently, the erasing efficiency is enhanced.

Please refer to FIG. 2M. When the read action is performed, the bit line BL receives the read voltage V_{R}, the source line SL receives the ground voltage (0V), the select gate line SG receives the read voltage V_{R}, the erase line EL receives the ground voltage (0V), and the assist gate line AG receives a voltage between the negative value of the assist gate line voltage −V_{AG} and the positive value of the assist gate line voltage V_{AG}. According to the voltage received by the assist gate line AG, the magnitude of a read current I_{R} is correspondingly adjusted.

When the read action is performed, the select transistor M_{S} is turned on, and the read current I_{R} is generated between the bit line BL and the source line SL. The storage state of the memory cell can be determined according to the magnitude of the read current I_{R}. For example, in case that electrons are stored in the floating gate 215, the magnitude of the read current I_{R} is very low (e.g., nearly zero). Consequently, it is determined that the memory cell is in a first storage state. Whereas, in case that no electrons are stored in the floating gate 215, the magnitude of the read current I_{R} is very high. Under this circumstance, it is determined that the memory cell is in a second storage state.

As mentioned above, the present invention provides two LDD processes to generate LDD regions with different dopant concentrations. Consequently, the floating gate transistor M_{F} with a short channel length to have a high channel resistance value. Please refer to FIG. 2F again. In the merged n-doped region 272, the n-LDD region 251 closer to the first side of the gate structure 225 of the floating gate transistor M_{F} has the lower dopant concentration. In the merged n-doped region 273, the n-LDD region 252 closer to the second side of the gate structure 225 of the floating gate transistor M_{F} has the lower dopant concentration. In the merged n-doped region 271, the n-LDD region 241 closer to the first side of the gate structure 223 of the select transistor M_{S} has the higher dopant concentration. In the merged n-doped region 272, the n-LDD region 242 closer to the first side of the gate structure 223 of the select transistor M_{S} has the higher dopant concentration. Since the dopant concentration difference near the channel may influence the channel resistance value of the floating gate transistor M_{F} and the channel resistance value of the select transistor M_{S}, the channel resistance value of the floating gate transistor M_{F} is greater than the channel resistance value of the select transistor M_{S}.

It is noted that the doping step of the first embodiment may be modified. Hereinafter, some variant examples of the doping step will be described. By using these variant examples, the floating gate transistor M_{F} with a short channel length will have a high channel resistance value.

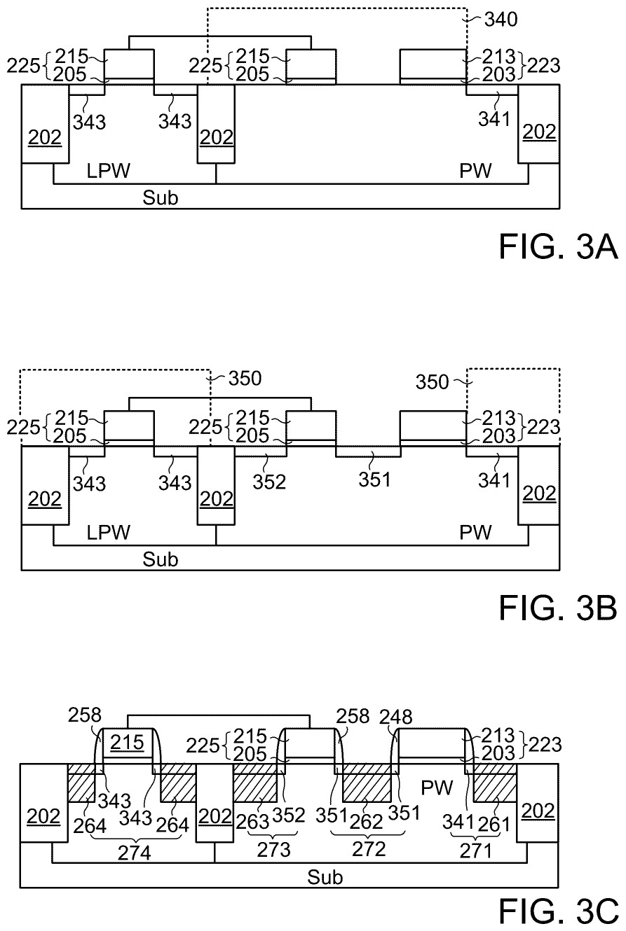

FIGS. 3A, 3B and 3C schematically illustrate a first variant example of the doping step in the manufacturing method of the first embodiment. The procedures of the doping step of this variant example are followed by the structure of FIG. 2B.

Please refer to FIG. 3A. Firstly, the gate structure 225, the gate structure 223 and the two side areas of the gate structure 225 in the region A are covered with a mask 340 shown in dotted lines. In addition, only a side region (e.g., the right region) of the gate structure 223 is exposed. Then, a first lightly doped drain process (LDD process) is performed. Consequently, n-type lightly doped drain regions (n-LDD regions) 341 and 343 are formed in the surface of the semiconductor substrate Sub uncovered by the mask 340. The n-LDD region 341 is formed under the surface of the region A and located beside a side (e.g., the right side) of the gate structure 223. The n-LDD region 343 is formed under the surface of the region B and located beside the gate structure 225.

Please refer to FIG. 3B. After the mask 340 is removed, the side (e.g., the right side) of the gate structure 223 in the region A and the region B are covered with a mask 350 shown in dotted lines. In other words, the region previously covered by mask 340 is exposed. Then, a second LDD process is performed. Consequently, n-type lightly doped drain regions (n-LDD regions) 351 and 352 are formed in the surface of the semiconductor substrate Sub uncovered by the mask 350. The n-LDD regions 351 and 352 are formed under the surface of the region A and respectively located beside the two sides of the gate structure 225.

For example, the masks 340 and 350 are photoresists. In an embodiment, the dopant concentration of the n-LDD regions 351 and 352 is smaller than the dopant concentration of the n-LDD regions 341 and 243.

Please refer to FIG. 3C. After the spacers 248 and 258 are formed, an n-type ion implantation process is performed on the surface of the semiconductor substrate Sub by using the two gate structures 223 and 225 and the two spacers 248 and 258 as masks. Consequently, three n-type ion implantation regions 261, 262 and 263 shown in oblique lines are formed on three sub-regions of the region A uncovered by the two gate structures 223 and 225 and the two spacers 248 and 258, and an n-type ion implantation region 264 shown in oblique lines is formed on the region B uncovered by the gate structure 225 and the spacer 258.

Please refer to FIG. 3C again. Then, the n-LDD region 341 and the n-type ion implantation regions 261 are collaboratively formed as a merged n-doped region 271. The merged n-doped region 271 is formed in the surface of the semiconductor substrate Sub and located beside a first side of the gate structure 223. The n-LDD region 351 and the n-type ion implantation regions 262 are collaboratively formed as a merged n-doped region 272. The merged n-doped region 272 is formed in the surface of the semiconductor substrate Sub and arranged between the second side of the gate structure 223 and the first side of the gate structure 225. The n-LDD region 352 and the n-type ion implantation regions 263 are collaboratively formed as a merged n-doped region 273. The merged n-doped region 273 is formed in the surface of the semiconductor substrate Sub and located beside the second side of the gate structure 225. The n-LDD region 343 and the n-type ion implantation regions 264 are collaboratively formed as a merged n-doped region 274. The merged n-doped region 274 is formed in the surface of the semiconductor substrate Sub and located beside the extension part of the gate structure 225.

Please refer to the comparison between the structure of FIG. 2F and the structure of FIG. 3C. The dopant concentration of the n-LDD region 242 at the left side of the gate structure 223 in the memory cell of FIG. 2F is higher than the dopant concentration of the n-LDD region 351 at the left side of the gate structure 223 in the memory cell of FIG. 3C. The dopant concentrations of the other n-LDD regions are identical.

Please refer to FIG. 3C again. In the merged n-doped region 272, the n-LDD region 351 closer to the first side of the gate structure 225 of the floating gate transistor M_{F} has the lower dopant concentration. In the merged n-doped region 273, the n-LDD region 352 closer to the second side of the gate structure 225 of the floating gate transistor M_{F} has the lower dopant concentration. In the merged n-doped region 271, the n-LDD region 341 closer to the first side of the gate structure 223 of the select transistor M_{S} has the higher dopant concentration. In the merged n-doped region 272, the n-LDD region 351 closer to the first side of the gate structure 223 of the select transistor M_{S} has the lower dopant concentration. Since the dopant concentration difference near the channel may influence the channel resistance value of the floating gate transistor M_{F} and the channel resistance value of the select transistor M_{S}, the channel resistance value of the floating gate transistor M_{F} is greater than the channel resistance value of the select transistor M_{S}.

The subsequent procedures of manufacturing the memory cell may be referred to FIGS. 2G and 2H, and the equivalent circuit is similar to that of FIG. 2I.

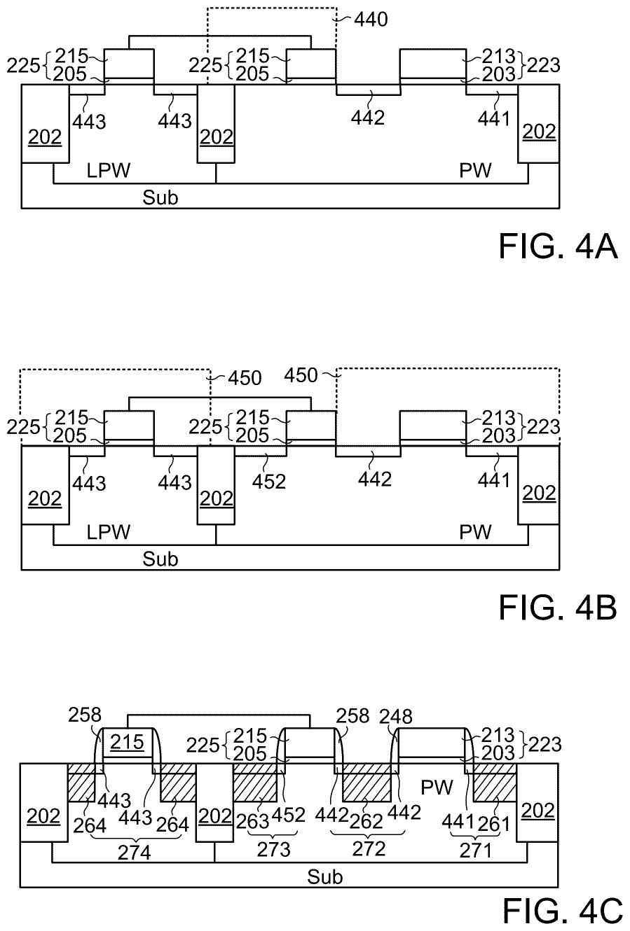

FIGS. 4A, 4B and 4C schematically illustrate a second variant example of the doping step in the manufacturing method of the first embodiment. The procedures of the doping step of this variant example are followed by the structure of FIG. 2B.

Please refer to FIG. 4A. Firstly, the gate structure 225 and a side (e.g., a left side) of the gate structure 225 in the region A are covered with a mask 440 shown in dotted lines. The gate structure 223 and its two side areas are exposed. In addition, the region B is exposed. Then, a first lightly doped drain process (LDD process) is performed. Consequently, n-type lightly doped drain regions (n-LDD regions) 441, 442 and 443 are formed in the surface of the semiconductor substrate Sub uncovered by the mask 440. The n-LDD region 441 is formed under the surface of the region A and located beside a side (e.g., the right side) of the gate structure 223. The n-LDD region 442 is formed under the surface of the region A and located beside another side (e.g., the left side) of the gate structure 223. The n-LDD region 443 is formed under the surface of the region B and located beside the gate structure 225.

Please refer to FIG. 4B. After the mask 440 is removed, the gate structure 223 (and its side areas) in the region A and the region B are covered with a mask 450 shown in dotted lines. In other words, the region previously covered by mask 440 is exposed. Then, a second LDD process is performed. Consequently, an n-type lightly doped drain region (n-LDD region) 452 is formed in the surface of the semiconductor substrate Sub uncovered by the mask 450. The n-LDD region 452 is formed under the surface of the region A and located beside a side (e.g., the left side) of the gate structure 225. For example, the masks 440 and 450 are photoresists. In an embodiment, the dopant concentration of the n-LDD region 452 is smaller than the dopant concentration of the n-LDD regions 441, 442 and 443.

Please refer to FIG. 4C. After the spacers 248 and 258 are formed, an n-type ion implantation process is performed on the surface of the semiconductor substrate Sub by using the two gate structures 223 and 225 and the two spacers 248 and 258 as masks. Consequently, three n-type ion implantation regions 261, 262 and 263 shown in oblique lines are formed on three sub-regions of the region A uncovered by the two gate structures 223 and 225 and the two spacers 248 and 258, and an n-type ion implantation region 264 shown in oblique lines is formed on the region B uncovered by the gate structure 225 and the spacer 258.

Please refer to FIG. 4C again. Then, the n-LDD region 441 and the n-type ion implantation regions 261 are collaboratively formed as a merged n-doped region 271. The merged n-doped region 271 is formed in the surface of the semiconductor substrate Sub and located beside a first side of the gate structure 223. The n-LDD region 442 and the n-type ion implantation regions 262 are collaboratively formed as a merged n-doped region 272. The merged n-doped region 272 is formed in the surface of the semiconductor substrate Sub and arranged between the second side of the gate structure 223 and the first side of the gate structure 225. The n-LDD region 452 and the n-type ion implantation regions 263 are collaboratively formed as a merged n-doped region 273. The merged n-doped region 273 is formed in the surface of the semiconductor substrate Sub and located beside the second side of the gate structure 225. The n-LDD region 443 and the n-type ion implantation regions 264 are collaboratively formed as a merged n-doped region 274. The merged n-doped region 274 is formed in the surface of the semiconductor substrate Sub and located beside the extension part of the gate structure 225.

Please refer to the comparison between the structure of FIG. 2F and the structure of FIG. 4C. The dopant concentration of the n-LDD region 251 at the right side of the gate structure 225 in the memory cell of FIG. 2F is lower than the dopant concentration of the n-LDD region 442 at the right side of the gate structure 225 in the memory cell of FIG. 4C. The dopant concentrations of the other n-LDD regions are identical.

Please refer to FIG. 4C again. In the merged n-doped region 272, the n-LDD region 442 closer to the first side of the gate structure 225 of the floating gate transistor M_{F} has the higher dopant concentration. In the merged n-doped region 273, the n-LDD region 452 closer to the second side of the gate structure 225 of the floating gate transistor M_{F} has the lower dopant concentration. In the merged n-doped region 271, the n-LDD region 441 closer to the first side of the gate structure 223 of the select transistor M_{S} has the higher dopant concentration. In the merged n-doped region 272, the n-LDD region 442 closer to the first side of the gate structure 223 of the select transistor M_{S} has the higher dopant concentration. Since the dopant concentration difference near the channel may influence the channel resistance value of the floating gate transistor M_{F} and the channel resistance value of the select transistor M_{S}, the channel resistance value of the floating gate transistor M_{F} is greater than the channel resistance value of the select transistor M_{S}.

The subsequent procedures of manufacturing the memory cell may be referred to FIGS. 2G and 2H, and the equivalent circuit is similar to that of FIG. 2I.

From the above descriptions, the channel resistance value of the floating gate transistor M_{F} is greater than the channel resistance value of the select transistor M_{S} by adjusting the dopant concentrations of the n-LDD regions in the merged n-doped regions 271, 272 and 273. The merged n-doped region 271 comprises a first n-LDD region, which is located beside a first side of the gate structure 223. The merged n-doped region 272 comprises a second n-LDD region and a third n-LDD region. The second n-LDD region is located beside a second side of the gate structure 223. The third n-LDD region is located beside a first side of the gate structure 225. The merged n-doped region 273 comprises a fourth n-LDD region, which is located beside a second side of the gate structure 225.

In the example off FIG. 2F, the dopant concentration of the fourth n-LDD region 252 and the dopant concentration of the third n-LDD region 251 are identical, the dopant concentration of the second n-LDD region 242 and the dopant concentration of the first n-LDD region 241 are identical, and the dopant concentration of the fourth n-LDD region 252 is lower than the dopant concentration of the first n-LDD region 241.

In the example off FIG. 3C, the dopant concentration of the fourth n-LDD region 352 and the dopant concentration of the third n-LDD region 351 are identical, the dopant concentration of the third n-LDD region 351 and the dopant concentration of the second n-LDD region 351 are identical, and the dopant concentration of the fourth n-LDD region 352 is lower than the dopant concentration of the first n-LDD region 341.

In the example off FIG. 4C, the dopant concentration of the third n-LDD region 442 and the dopant concentration of the second n-LDD region 442 are identical, the dopant concentration of the second n-LDD region 442 and the dopant concentration of the first n-LDD region 441, and the dopant concentration of the fourth n-LDD region 452 is lower than the dopant concentration of the first n-LDD region 441.

In the above embodiments, the n-LDD regions 243, 343, 443, and 543 in the region B are all formed in the first LDD process, and their dopant concentrations are relatively high. It is noted that numerous modifications and alterations may be made while retaining the teachings of the invention. For example, in another embodiment, the n-LDD region in the region B is completed by using two LDD processes, and the dopant concentration is lower. In some other embodiments, the sequence of the two LDD processes is changed. For example, the dopant concentration in the first LDD process is lower, and the dopant concentration in the second LDD process is higher.

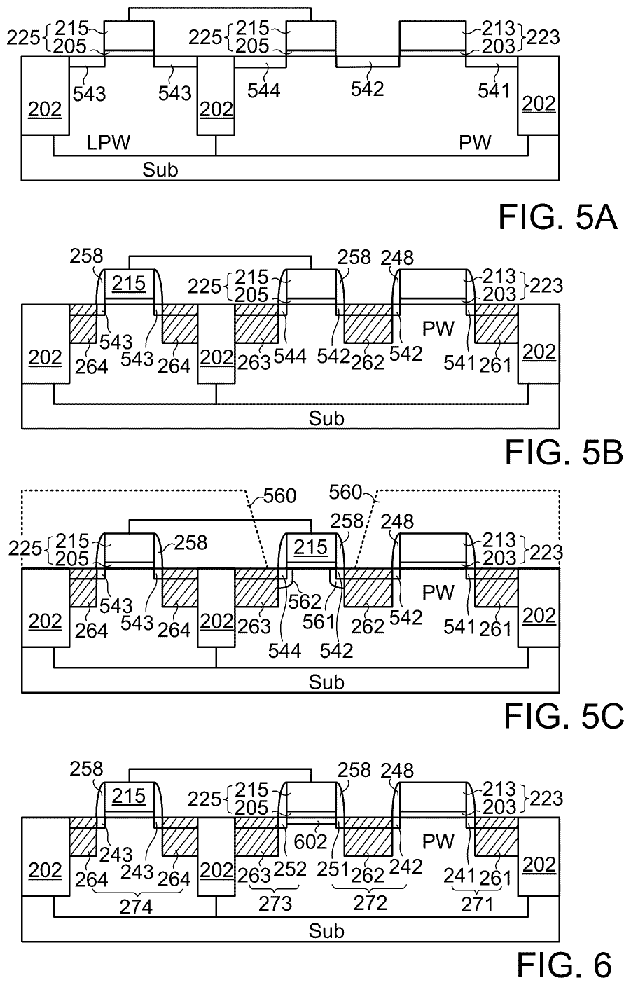

Of course, the doping step may be further modified to achieve the concentration distribution of FIG. 2F, FIG. 3C or FIG. 4C. FIGS. 5A, 5B and 5C schematically illustrate a third variant example of the doping step in the manufacturing method of the first embodiment. The procedures of the doping step of this variant example are followed by the structure of FIG. 2B.

Please refer to FIG. 5A. Firstly, a first lightly doped drain process (LDD process) is performed by using the gate structure 223 and the gate structure 225 as masks. Consequently, n-type lightly doped drain regions (n-LDD regions) 541, 542 and 543 are formed in the surface of the semiconductor substrate Sub uncovered by the masks. The n-LDD region 541 is formed under the surface of the semiconductor substrate Sub and located beside a first side of the gate structure 223. The n-LDD region 542 is formed under the surface of the semiconductor substrate Sub and arranged between the second side of the gate structure 223 and first side of the gate structure 225. The n-LDD region 544 is formed under the surface of the semiconductor substrate Sub and located beside a second side of the gate structure 225. The n-LDD region 543 is formed under the surface of the region B and located beside the gate structure 225.

Please refer to FIG. 5B. After the spacers 248 and 258 are formed, an n-type ion implantation process is performed on the surface of the semiconductor substrate Sub by using the two gate structures 223 and 225 and the two spacers 248 and 258 as masks. Consequently, three n-type ion implantation regions 261, 262 and 263 shown in oblique lines are formed on three sub-regions of the region A uncovered by the two gate structures 223 and 225 and the two spacers 248 and 258, and an n-type ion implantation region 264 shown in oblique lines is formed on the region B uncovered by the gate structure 225 and the spacer 258.

In this embodiment, the dopant concentrations of the n-LDD regions 541, 542 and 544 are identical. As mentioned above, it is preferred that the channel resistance value of the floating gate transistor M_{F} is greater than the channel resistance value of the select transistor M_{S}. Please refer to FIG. 5C. In order to achieve this purpose, the surface of the semiconductor substrate Sub is covered with a mask 560, and only the gate structure 225 in the region A and its two side areas are exposed. Then, an anti-punch through implantation (APT) process is performed. Consequently, two anti-punch through implantation (APT) regions 561 and 562 are formed. The APT region 561 is contacted with the n-LDD region 542. The APT region 562 is contacted with the n-LDD region 544. For example, the APT process is a halo implantation process or a pocket implantation process. Since the APT regions 561 and 562 are respectively contacted with the n-LDD regions 542 and 544, which results in higher resistance and a higher electric field occurring in the n-LDD regions 542 and 544. Consequently, the channel resistance value of the floating gate transistor M_{F} is greater than the channel resistance value of the select transistor M_{S}.

After the mask 560 is removed, the subsequent procedures of manufacturing the memory cell may be referred to FIGS. 2G and 2H, and the equivalent circuit is similar to that of FIG. 2I.

In the doping step of FIGS. 5A, 5B and 5C, the APT regions 561 and 562 are respectively located beside the n-LDD regions 542 and 544. It is noted that numerous modifications and alterations may be made while retaining the teachings of the invention. For example, in a variant example, a single APT region is contacted with the n-LDD region 544 beside the second side of the gate structure 225. In another variant example, a single APT region is contacted with the n-LDD region 542 beside the first side of the gate structure 225. In another variant example, three APT regions are formed. Two of the three APT regions are respectively contacted with the n-LDD regions 542 and 544 beside two sides of the gate structure 225, and one of the three APT regions is contacted with the n-LDD region 541 beside the first side of the gate structure 223. However, no APT region is contacted with the n-LDD region 542 beside the second side of the gate structure 223. Consequently, the channel resistance value of the floating gate transistor M_{F} is greater than the channel resistance value of the select transistor M_{S}.

Moreover, it is to be noted that the conductivity of the APT region described above may be n-type or p-type; however, p-type is preferred due to better performance.

In some other embodiments, a p-type channel implantation process is performed on the region under the gate structure 225. Consequently, the channel resistance value of the floating gate transistor M_{F} is increased. FIG. 6 schematically illustrates a fourth variant example of the doping step in the manufacturing method of the first embodiment. The procedures of the doping step of this variant example are followed by the structure of FIG. 2F.

After the structure of FIG. 2F is subjected to a p-type channel implantation process, a p-type channel doped region 602 is formed. The p-type channel doped region 602 is formed in the surface of the semiconductor substrate Sub and located under the gate structure 225. Since the p-type channel doped region 602 and the merged n-doped regions 272 and 273 have different dopant types, the channel resistance value of the floating gate transistor M_{F} can be increased. Similarly, the p-type channel implantation process can be applied to the structure of FIG. 3C, FIG. 4C, FIG. 5B or FIG. 5C. Consequently, the p-type channel doped region 602 is formed in the surface of the semiconductor substrate Sub and located under the gate structure 225.

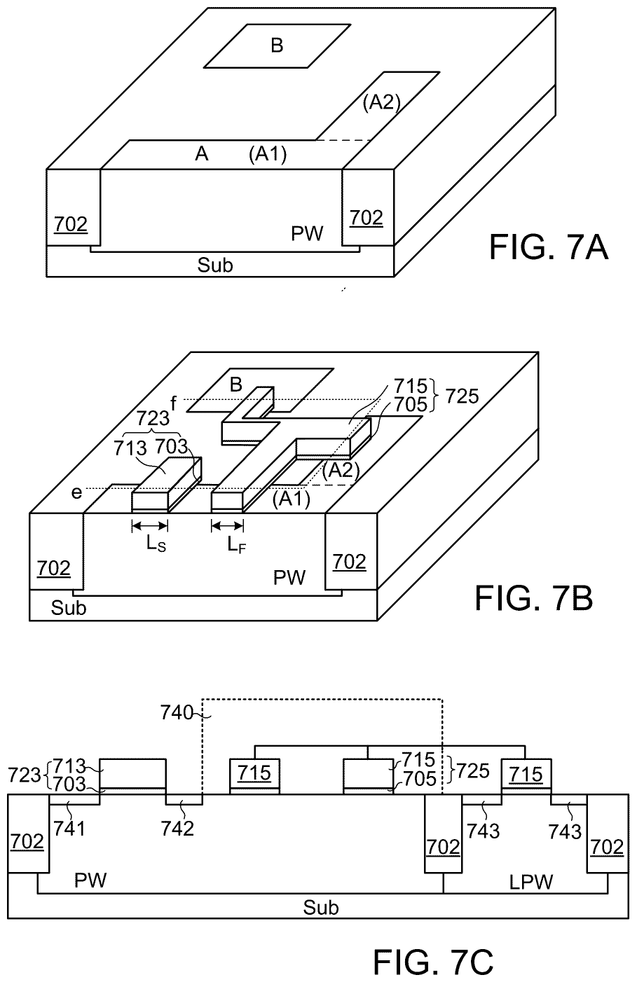

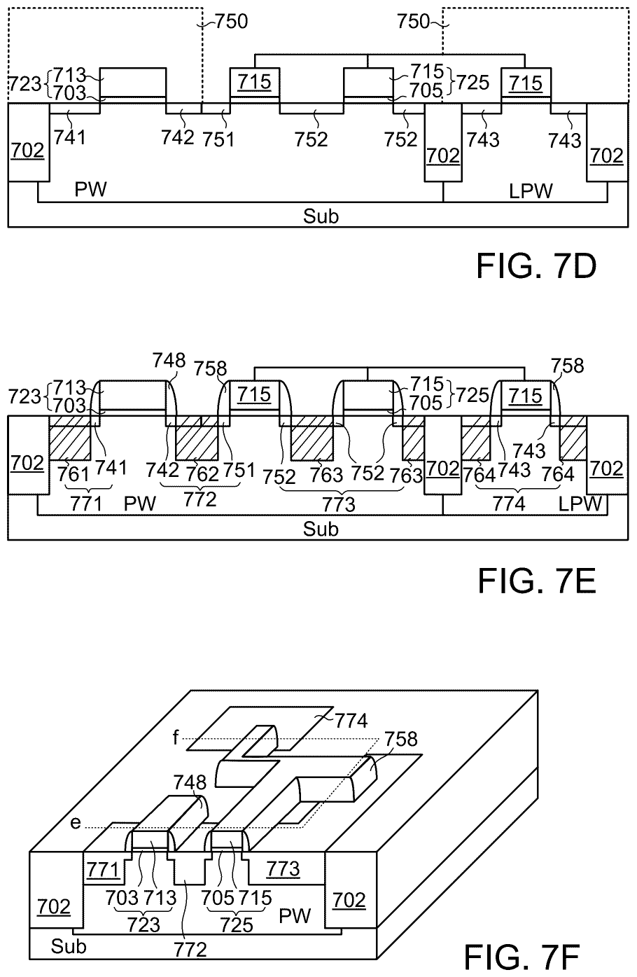

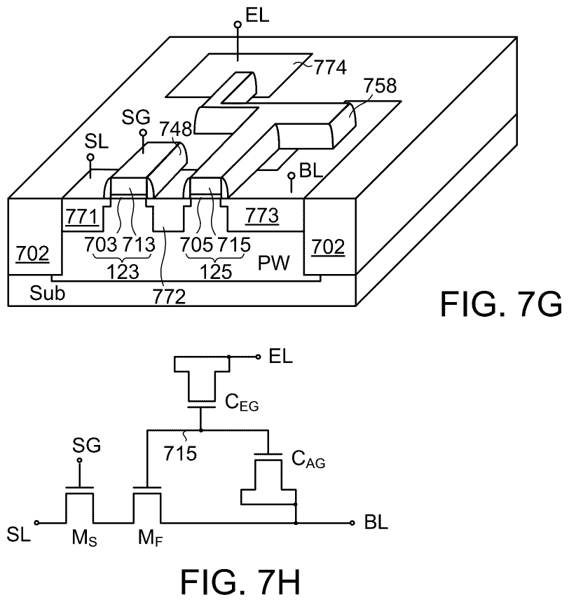

FIGS. 7A to 7G schematically illustrate the steps of a method of manufacturing a single-poly non-volatile memory cell according to a second embodiment of the present invention. FIG. 7H is a schematic equivalent circuit diagram of the single-poly non-volatile memory cell according to the second embodiment of the present invention.

As shown in FIG. 7A, an isolation structure forming step is performed. Firstly, an isolation structure 702 is formed on a p-type substrate Sub. Due to the isolation structure 702, a region A and a region B are defined. The region B is a rectangular region. The region A is composed of two rectangular sub-regions A1 and A2. Then, a well region forming step is performed. A first well region (e.g., a P-well region) is formed in the surface of the semiconductor substrate Sub corresponding to the region A. In addition, a second well region is formed in the surface of the semiconductor substrate Sub corresponding to the region B. For example, the second well region is a lightly doped P-well region LPW, a P-well region PW or an N-well region NW. In the subsequent steps, a floating gate transistor, a select transistor and an assist gate region are formed in the region A, and an erase gate region is formed in the region B.

Then, a gate structure forming step is performed. As shown in FIG. 7B, two gate oxide layers 703 and 705 are formed. Then, two polysilicon gate layers 713 and 715 are formed on the two gate oxide layers 703 and 705, respectively. Consequently, two gate structures 723 and 725 are formed. The two gate structures 723 and 725 are formed on the surface of the region A. In addition, the region A is divided into three sub-regions by the two gate structures 723 and 725. The gate structures 723 and 725 are formed on the surface corresponding to the region A1. The first sub-region is located beside a left side of the gate structure 723. The second sub-region 723 is arranged between the right side of the gate structure 723 and the left side of the gate structure 725. The third sub-region is located beside the right side of the gate structure 725 (including the region A2). In other words, the third sub-region is an L-shaped sub-region.

Moreover, two extension segments are externally extended from the gate structure 725 through the surface of the isolation structure 702. The first extension segment of the gate structure 725 is externally extended to the region B. In addition, a portion of the region B is covered by the first extension segment of the gate structure 725. The second extension segment of the gate structure 725 is externally extended to the sub-region A2. In addition, a portion of the sub-region A2 is covered by the second extension segment of the gate structure 725. In this embodiment, the polysilicon gate layer 715 of the gate structure 725 is served as a floating gate. The polysilicon gate layer 713 of the gate structure 723 is served as a select gate. In an embodiment, the channel length L_{F} of the floating gate transistor is smaller than the channel length L_{S} of the select transistor, i.e., L_{F}<L_{S}.

Hereinafter, the doping step will be described in more details with reference to the cross-sectional view of the structure shown in FIG. 7B and taken along the line e-f.

Please refer to FIG. 7C. Firstly, the gate structure 725 and its two side areas in the region A are covered with a mask 740 shown in dotted lines. The gate structure 723 and its two side areas are exposed. In addition, the region B is exposed. That is, only a part of the surface between the gate structure 723 and the gate structure 725 is covered by the mask 740, and the other part of the surface between the gate structure 723 and the gate structure 725 is not covered by the mask 740. Then, a first lightly doped drain process (LDD process) is performed. Consequently, n-type lightly doped drain regions (n-LDD regions) 741, 742 and 743 are formed in the surface of the semiconductor substrate Sub uncovered by the mask 740. The n-LDD regions 741 and 742 are formed under the surface of the region A and respectively located beside the two sides of the gate structure 723. The n-LDD region 743 is formed under the surface of the region B and located beside the gate structure 725.

Please refer to FIG. 7D. After the mask 740 is removed, the gate structure 723 (and its side areas) in the region A and the region B are covered with a mask 750 shown in dotted lines. In other words, the region previously covered by mask 740 is exposed. Then, a second LDD process is performed. Consequently, n-type lightly doped drain regions (n-LDD regions) 751 and 752 are formed in the surface of the semiconductor substrate Sub uncovered by the mask 750. The n-LDD regions 751 and 752 are formed under the surface of the region A and respectively located beside the two sides of the gate structure 725.

For example, the masks 740 and 750 are photoresists. In an embodiment, the dopant concentration of the n-LDD regions 751 and 752 is smaller than the dopant concentration of the n-LDD regions 741, 742 and 743.

Please refer to FIG. 7E. After the mask 750 is removed, a spacer 748 is formed on the sidewall of the gate structure 723, and a spacer 758 is formed on the sidewall of the gate structure 725. After the spacers 748 and 758 are formed, an n-type ion implantation process is performed on the surface of the semiconductor substrate Sub by using the two gate structures 723 and 725 and the two spacers 748 and 758 as masks. Consequently, three n-type ion implantation regions 761, 762 and 763 shown in oblique lines are formed on three sub-regions of the region A uncovered by the two gate structures 723 and 725 and the two spacers 748 and 758, and an n-type ion implantation region 764 shown in oblique lines is formed on the region B uncovered by the gate structure 725 and the spacer 758. Especially, the n-type ion implantation regions 761, 762, 763, and 764 have the highest doping concentration, and their dopant concentration is greater than the dopant concentration of the n-LDD regions 741, 742, 743, 751 and 752.

Please refer to FIG. 7E. Then, the n-LDD region 741 and the n-type ion implantation regions 761 are collaboratively formed as a merged n-doped region 771. The merged n-doped region 771 is formed in the surface of the semiconductor substrate Sub and located beside a first side of the gate structure 723. The n-LDD region 742, the n-LDD region 751 and the n-type ion implantation regions 762 are collaboratively formed as a merged n-doped region 772. The merged n-doped region 772 is formed in the surface of the semiconductor substrate Sub and arranged between the second side of the gate structure 723 and the first side of the gate structure 775. The n-LDD region 752 and the n-type ion implantation regions 763 are collaboratively formed as a merged n-doped region 773. The merged n-doped region 773 is formed in the surface of the semiconductor substrate Sub and located beside the second side of the gate structure 775. The n-LDD region 743 and the n-type ion implantation regions 764 are collaboratively formed as a merged n-doped region 774. The merged n-doped region 774 is formed in the surface of the semiconductor substrate Sub and located beside the extension part of the gate structure 725. The perspective view of the structure of FIG. 7E is shown in FIG. 7F.

In the region A, the gate structure 723 and the merged n-doped regions 771 and 772 on its two sides are collaboratively formed as a select transistor. In addition, the gate structure 725 and the two merged n-doped regions 772 and 773 on its two sides are collaboratively formed as a floating gate transistor. In this embodiment, the floating gate transistor and the select transistor are n-type transistors and constructed in the P-well region PW. That is, the body terminal of the floating gate transistor and the body terminal of the select transistor are connected with the P-well region PW.

The n-doped region 773 is a drain/source terminal of the floating transistor. In addition, the n-doped region 773 can be served as the assist gate region. That is, the second extension segment of the gate structure 725 is externally extended to a region beside the assist gate region. Consequently, the assist gate region and the gate structure 725 are collaboratively formed as an n-type transistor. In addition, the n-type transistor is connected as a MOS capacitor.

In the region B, the n-type doped region 774 is the erase gate region. The first extension segment of the gate structure 725 is externally extended to a region beside the erase gate region. Consequently, the erase gate region and the gate structure 725 are collaboratively formed as an n-type transistor. In addition, the n-type transistor is connected as another MOS capacitor.

Please refer to FIG. 7G. After a step of forming metal conductor lines is completed, the memory cell of this embodiment is fabricated. That is, the n-type doped region 771 is connected with a source line SL, the n-type doped region 773 is connected with a bit line BL, the n-type doped region 775 is connected with an erase line EL, and the polysilicon gate layer 713 is connected with a select gate line SG.

As shown in FIG. 7H, the equivalent circuit of the memory cell of this embodiment comprises a select transistor M_{S}, a floating gate transistor M_{F}, a first MOS capacitor C_{EG} and a second MOS capacitor C_{AG}.

The gate terminal of the select transistor M_{S} is connected with a select gate line SG. The first drain/source terminal of the select transistor M_{S} is connected with the source line SL. The first drain/source terminal of the floating gate transistor M_{F} is connected with the second drain/source terminal of the select transistor M_{S}. The second drain/source terminal of the floating gate transistor M_{F} is connected with the bit line BL. The first terminal of the first MOS capacitor C_{EG} is connected with the floating gate 715 of the floating gate transistor M_{F}. The second terminal of the first MOS capacitor C_{EG} is connected with the erase line EL. The first terminal of the second MOS capacitor C_{AG} is connected with the floating gate 715 of the floating gate transistor M_{F}. The second terminal of the second MOS capacitor C_{AG} is connected with the bit line BL.

Since the memory cell of the second embodiment comprises two transistors M_{S} and M_{F} and two capacitors C_{EG} and C_{AG}, this memory cell may be referred to as a 2T2C cell.

By providing proper bias voltage to the memory cell of the second embodiment, a program action (PGM), an erase action (ERS) or a read action (Read) can be performed. In this embodiment, the memory cell is not equipped with the assist gate line AG. Consequently, in the bias voltage table shown in FIG. 2J, the bias voltages corresponding to the assist gate line AG are ignored. The operations of the memory cell of the second embodiment are similar to those of the first embodiment, and not redundantly described herein.

Please refer to FIG. 7E again. In the merged n-doped region 772, the n-LDD region 751 closer to the first side of the gate structure 725 of the floating gate transistor M_{F} has the lower dopant concentration. In the merged n-doped region 773, the n-LDD region 752 closer to the second side of the gate structure 725 of the floating gate transistor M_{F} has the lower dopant concentration. In the merged n-doped region 771, the n-LDD region 741 closer to the first side of the gate structure 723 of the select transistor M_{S} has the higher dopant concentration. In the merged n-doped region 772, the n-LDD region 742 closer to the first side of the gate structure 723 of the select transistor M_{S} has the higher dopant concentration. Since the dopant concentration difference near the channel influences the channel resistance value of the floating gate transistor M_{F} and the channel resistance value of the select transistor M_{S}, the channel resistance value of the floating gate transistor M_{F} is greater than that of the select transistor M_{S}.

It is noted that the doping step of the second embodiment may be modified by referring to the variant examples of the first embodiment. That is, the first variant example of FIGS. 3A, 3B and 3C, the second variant example of FIGS. 4A, 4B and 4C, the third variant example of FIGS. 5A, 5B and 5C or the fourth variant example of FIG. 6 may be applied to the memory cell of the second embodiment. By using these variant examples, the channel resistance value of the floating gate transistor M_{F} is greater than the channel resistance value of the select transistor M_{S}.

In the above embodiments, the floating gate transistor M_{F} and the select transistor M_{S} of the memory cell are n-type transistors. That is, the LDD regions are n-type LDD regions, and the ion implantation regions are n-type ion implantation regions. It is noted that numerous modifications and alterations may be made while retaining the teachings of the invention. For example, in another embodiment, the floating gate transistor M_{F} and the select transistor M_{S} of the memory cell are p-type transistors. That is, the LDD regions are p-type LDD regions, and the ion implantation regions are p-type ion implantation regions. In addition, the p-type LDD regions and the p-type ion implantation regions are formed in an N-well region. Similarly, the MOS transistors C_{MOS}, C_{EG} and C_{AG} are p-type transistors.

From the above descriptions, the present invention provides an erasable programmable single-poly non-volatile memory cell. In the above embodiment, the memory cell is the 2T2C cell. Of course, the concepts of the present invention can be applied to the 2T1C cell. For example, in the example of FIG. 2I, the memory cell without the plate capacitors C_{P1}, C_{P2} and C_{P3} may be regarded as the 2T1C cell. Similarly, in the example of FIG. 7H, the memory cell without the MOS capacitor C_{AG} is regarded as the 2T1C cell.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An erasable programmable single-poly non-volatile memory cell, comprising:
an isolation structure formed on the semiconductor substrate, wherein a surface of the semiconductor substrate is divided into a first region and a second region by the isolation structure;
a first well region formed in the surface of the semiconductor substrate corresponding to the first region;
a second well region formed in the surface of the semiconductor substrate corresponding to the second region;
a first gate structure and a second gate structure formed on the surface of the semiconductor substrate corresponding to the first region, wherein an area in the surface of the semiconductor substrate corresponding to the first region is divided into a first merged doped region, a second merged doped region and a third merged doped region by the first gate structure and a second gate structure; and
a fourth merged doped region formed in the surface of the semiconductor substrate corresponding to the second region and located beside a side of the second gate structure,
wherein the first merged doped region is located beside a first side of the first gate structure, the second merged doped region is arranged between a second side of the first gate structure and a first side of the second gate structure, and the third merged doped region is located beside a second side of the second gate structure,
wherein the second gate structure is externally extended to the second region through a surface of the isolation structure, and a portion of the second region is covered by the second gate structure,
wherein the first merged doped region, the first gate structure and the second merged doped region are collaboratively formed as a select transistor, the second merged doped region, the second gate structure and the third merged doped region are collaboratively formed as a floating gate transistor, and the second gate structure and the fourth merged doped region are collaboratively formed as a first MOS capacitor, wherein a channel resistance value of the floating gate transistor is greater than a channel resistance value of the select transistor.

2. The single-poly non-volatile memory cell as claimed in claim 1, wherein the first merged doped region contains a first ion implantation region and a first lightly doped drain region, the second merged doped region contains a second ion implantation region, a second lightly doped drain region and a third lightly doped drain region, and the third merged doped region contains a third ion implantation region and a fourth lightly doped drain region, wherein the first lightly doped drain region is located beside the first side of the first gate structure, the second lightly doped drain region is located beside the second side of the first gate structure, the third lightly doped drain region is located beside the first side of the second gate structure, and the fourth lightly doped drain region is located beside the second side of the first gate structure.

3. The single-poly non-volatile memory cell as claimed in claim 2, wherein a dopant concentration of the first lightly doped drain region and a dopant concentration of the second lightly doped drain region are identical, a dopant concentration of the third lightly doped drain region and a dopant concentration of the fourth lightly doped drain region are identical, and the dopant concentration of the fourth lightly doped drain region is lower than the dopant concentration of the first lightly doped drain region.

4. The single-poly non-volatile memory cell as claimed in claim 2, wherein a dopant concentration of the fourth lightly doped drain region, a dopant concentration of the third lightly doped drain region and a dopant concentration of the second lightly doped drain region are identical, and the dopant concentration of the fourth lightly doped drain region is lower than a dopant concentration of the first lightly doped drain region.

5. The single-poly non-volatile memory cell as claimed in claim 2, wherein a dopant concentration of the first lightly doped drain region, a dopant concentration of the second lightly doped drain region and a dopant concentration of the third lightly doped drain region are identical, and a dopant concentration of the fourth lightly doped drain region is lower than the dopant concentration of the first lightly doped drain region.

6. The single-poly non-volatile memory cell as claimed in claim 2, further comprising a first anti-punch through implantation region, wherein the first anti-punch through implantation region is contacted with the fourth lightly doped drain region.

7. The single-poly non-volatile memory cell as claimed in claim 2, further comprising a first anti-punch through implantation region, wherein the first anti-punch through implantation region is contacted with the third lightly doped drain region.

8. The single-poly non-volatile memory cell as claimed in claim 2, further comprising a first anti-punch through implantation region and a second anti-punch through implantation region, wherein the first anti-punch through implantation region is contacted with the fourth lightly doped drain region, and the second anti-punch through implantation region is contacted with the third lightly doped drain region.

9. The single-poly non-volatile memory cell as claimed in claim 2, further comprising a first anti-punch through implantation region, a second anti-punch through implantation region and a third anti-punch through implantation region, wherein the first anti-punch through implantation region is contacted with the fourth lightly doped drain region, the second anti-punch through implantation region is contacted with the third lightly doped drain region, and the third anti-punch through implantation region is contacted with the second lightly doped drain region.

10. The single-poly non-volatile memory cell as claimed in claim 2, further comprising a first anti-punch through implantation region, a second anti-punch through implantation region and a third anti-punch through implantation region, wherein the first anti-punch through implantation region is contacted with the fourth lightly doped drain region, the second anti-punch through implantation region is contacted with the third lightly doped drain region, and the third anti-punch through implantation region is contacted with the first lightly doped drain region.

11. The single-poly non-volatile memory cell as claimed in claim 2, further comprising a channel doped region, wherein the channel doped region is formed in the surface of the semiconductor substrate and located under the second gate structure, wherein the channel doped region and the second merged doped region have different dopant types.

12. The single-poly non-volatile memory cell as claimed in claim 1, further comprising a third gate structure, wherein the third gate structure is formed on the isolation structure and located beside a first lateral side of the second gate structure, and the third gate structure and the third gate structure are collaboratively formed as a first poly/poly plate capacitor.

13. The single-poly non-volatile memory cell as claimed in claim 12, further comprising a fourth gate structure, wherein the fourth gate structure is formed on the isolation structure and located beside a second lateral side of the second gate structure, the fourth gate structure and the second gate structure are collaboratively formed as a second poly/poly plate capacitor, and the second poly/poly plate capacitor and the first poly/poly plate capacitor are connected with each other in parallel.

14. The single-poly non-volatile memory cell as claimed in claim 12, further comprising a metal layer, wherein the metal layer is formed over the second gate structure, the metal layer and the second gate structure are collaboratively formed as a metal/poly plate capacitor, and the metal/poly plate capacitor and the first poly/poly plate capacitor are connected with each other in parallel.

15. The single-poly non-volatile memory cell as claimed in claim 12, wherein the third gate structure is connected with an assist gate line, the first gate structure is connected with a select gate line, the first merged doped region is connected with a source line, the third merged doped region is connected with a bit line, and the fourth merged doped region is connected with an erase line.

16. The single-poly non-volatile memory cell as claimed in claim 15, wherein when a program action is performed, the source line receives a ground voltage, the select gate line receives a program voltage, the bit line receives the program voltage, the erase line receives a first voltage in a range between the ground voltage and an erase voltage, and the assist gate receives a second voltage in a range between the ground voltage and an assist gate line voltage, wherein the assist gate voltage is higher than the erase voltage, the erase voltage is higher than the program voltage, and the program voltage is higher the ground voltage.

17. The single-poly non-volatile memory cell as claimed in claim 15, wherein when an erase action is performed, the source line receives a ground voltage, the select gate line receives the ground voltage, the bit line receives the ground voltage, the erase line receives an erase voltage, and the assist gate receives a voltage in a range between a negative value of an assist gate voltage and the ground voltage, wherein the assist voltage is higher than the erase voltage, and the erase voltage is higher than the ground voltage.

18. The single-poly non-volatile memory cell as claimed in claim 15, wherein when a read action is performed, the source line receives a ground voltage, the select gate line receives a read voltage, the bit line receives the read voltage, the erase line receives the ground voltage, the assist gate line receives a voltage in a range between a negative value of an assist gate line voltage and a positive value of the assist gate voltage, wherein the assist gate voltage is higher than the read voltage, and the read voltage is higher than the ground voltage.

19. The single-poly non-volatile memory cell as claimed in claim 1, wherein the second gate structure comprises an extension part, which is extended to the third merged doped region through the surface of the isolation structure, and the extension part of the second gate structure and the third doped region are collaboratively formed as a second MOS capacitor, wherein the first gate structure is connected with a select gate line, the first merged doped region is connected with a source line, the third merged doped region is connected with a bit line, and the fourth merged doped region is connected with an erase line.

20. The single-poly non-volatile memory cell as claimed in claim 1, wherein a channel length of the floating gate transistor is smaller than a channel length of the select transistor.
